(19) United States
(12) Patent Application Publication
(10) Pub. No.: US 2026/0015764 A1
(43) Pub. Date: Jan. 15, 2026

(54) SEMICONDUCTOR CRYSTAL MANUFACTURING APPARATUS

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP)

(72) Inventors: TAKAHIRO KANDA, Nisshin-shi (JP); NOBUYUKI OYA, Nisshin-shi (JP)

(21) Appl. No.: 19/174,160

(22) Filed: Apr. 9, 2025

(30) Foreign Application Priority Data
Jul. 9, 2024 (JP) 2024-110295

(51) Int. Cl. C30B 25/08; C30B 25/20; C30B 29/36

(52) U.S. Cl. CPC C30B 25/08; C30B 25/20; C30B 29/36

(57) ABSTRACT

In a semiconductor crystal manufacturing apparatus, a seed crystal made of a semiconductor is disposed on a pedestal arranged in a vacuum vessel. A semiconductor source gas is supplied to the seed crystal to grow a crystal on a surface of the seed crystal. The semiconductor crystal manufacturing apparatus includes: a heating device having an induction heating coil to heat a heated object arranged in the vacuum vessel; and a radiation suppressing member arranged between the heated object and the induction heating coil to suppresses radiation to the induction heating coil from the heated object heated by induction heating of the induction heating coil. The radiation suppressing member is a fibrous member arranged to surround the heated object.

### CROSS REFERENCE TO RELATED APPLICATION

This application is based on Japanese Patent Application No. 2024-110295 filed on Jul. 9, 2024, the disclosure of which is incorporated herein by reference.

### TECHNICAL FIELD

The present disclosure relates to a semiconductor crystal manufacturing apparatus to manufacture a semiconductor crystal by growing a crystal on a surface of a seed crystal made of a semiconductor.

### BACKGROUND

In a semiconductor crystal manufacturing apparatus, a seed crystal made of a semiconductor is disposed on a pedestal arranged in a vacuum chamber. A semiconductor source gas is supplied from a lower side of the seed crystal to grow a semiconductor crystal on the surface of the seed crystal.

### SUMMARY

According to one aspect of the present disclosure, in a semiconductor crystal manufacturing apparatus, a seed crystal made of a semiconductor is disposed on a pedestal arranged in a vacuum vessel, and a semiconductor source gas is supplied to the seed crystal to grow a semiconductor crystal on a surface of the seed crystal. The semiconductor crystal manufacturing apparatus includes: a heating device having an induction heating coil to heat a heated object disposed in the vacuum vessel; and a radiation suppressing member disposed between the heated object and the induction heating coil, to suppress radiation from the heated object to the induction heating coil, the heated object being heated by induction heating of the induction heating coil. The radiation suppressing member is a fibrous member disposed to surround the heated object.

### BRIEF DESCRIPTION OF DRAWINGS

FIG. 1 is a schematic cross-sectional view showing a semiconductor crystal manufacturing apparatus according to an embodiment.

FIG. 2 is a schematic cross-sectional view showing a semiconductor crystal manufacturing apparatus according to a modification.

### DETAILED DESCRIPTION

In a semiconductor crystal manufacturing apparatus, a seed crystal made of a semiconductor is arranged on a pedestal in a vacuum vessel. A semiconductor source gas is supplied from a lower side of the seed crystal to grow a semiconductor crystal on the surface of the seed crystal. Specifically, the semiconductor crystal manufacturing apparatus includes a heating device. The heating device includes an induction heating coil that inductively heats a heated object disposed within the vacuum vessel. A radiation suppressing member is disposed between the heated object and the induction heating coil, for suppressing radiation from the heated object, which is heated by induction heating, to the induction heating coil.

In a semiconductor crystal manufacturing apparatus, a radiation suppressing member is disposed between an induction heating coil and a heated object. Therefore, even if the heated object is heated by the induction heating coil during the crystal growth of the semiconductor crystal, it is possible to block the radiation towards the induction heating coil. This makes it possible to restrict damage to the induction heating coil and to stably perform heating for a long period of time using the induction heating coil.

In a semiconductor crystal manufacturing apparatus, the radiation suppressing member is a radiation suppressing tube, specifically, an annular tubular member made of a material capable of suppressing radiation from a heated object (for example, a ceramic material such as alumina or mullite). Since the radiation suppressing tube is a rigid member made of a solid bulk material, it is difficult to correspond to complex shapes. In addition, since the shape of the radiation suppressing tube cannot follow the thermal expansion and deformation of the heated object, there is a concern that components adjacent to the radiation suppressing tube in the furnace (for example, protective members for the induction heating coil and the heated object) may be damaged.

The present disclosure provides a semiconductor crystal manufacturing apparatus that is capable of heating for a long period of time using an induction heating coil more stably than ever before.

According to one aspect of the present disclosure, in a semiconductor crystal manufacturing apparatus, a seed crystal made of a semiconductor is disposed on a pedestal in a vacuum vessel, and a semiconductor source gas is supplied to the seed crystal to grow a crystal on a surface of the seed crystal. The semiconductor crystal manufacturing apparatus includes: a heating device having an induction heating coil to heat a heated object disposed in the vacuum vessel; and a radiation suppressing member disposed between the heated object and the induction heating coil, to suppress radiation from the heated object to the induction heating coil, the heated object being heated by induction heating of the induction heating coil. The radiation suppressing member is a fibrous member disposed to surround the heated object.

Exemplary embodiments and specific examples of the present disclosure will be described below with reference to the drawings.

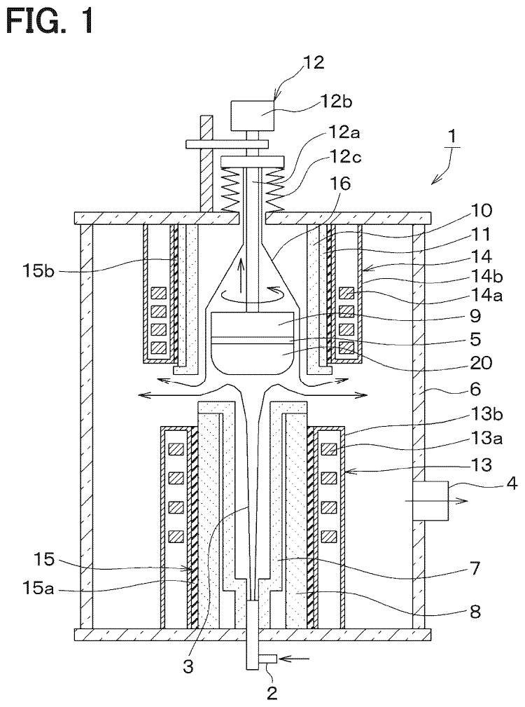

FIG. 1 shows a schematic cross-sectional view of a SiC single crystal manufacturing apparatus 1 as a semiconductor crystal manufacturing apparatus according to an embodiment. The configuration of the SiC single crystal manufacturing apparatus 1 will be described below with reference to FIG. 1.

The SiC single crystal manufacturing apparatus 1 supplies a source gas 3 through an inlet 2 provided at the bottom. The source gas 3 contains silicon and carbon, which are raw materials for SiC, together with a carrier gas. For example, the source gas 3 contains a mixed gas of a silane-based gas such as silane which serves as a silicon-containing gas and a hydrocarbon-based gas such as propane which serves as a carbon-containing gas. The SiC single crystal manufacturing apparatus 1 discharges unreacted gases through the exhaust port 4. In this manner, the SiC single crystal manufacturing apparatus 1 supplies the source gas 3 from the lower side of the seed crystal 5, which is a SiC single crystal substrate arranged inside the apparatus, thereby growing a SiC single crystal 20 on the seed crystal 5.

The SiC single crystal manufacturing apparatus 1 includes a vacuum vessel 6, a reaction vessel 7, an insulating material 8, a pedestal 9, a guide 10, a peripheral insulating material 11, a rotary lifting mechanism 12, a first heating device 13, a second heating device 14, and a radiation suppressing member 15.

The vacuum vessel 6 is made of quartz glass or the like, and has a hollow cylindrical shape to introduce and discharge the source gas 3. The vacuum vessel 6 houses the other components of the SiC single crystal manufacturing apparatus 1, and is configured to lower the pressure in the internal space by vacuum. The inlet 2 for the source gas 3 is provided at the bottom of the vacuum vessel 6. The exhaust port 4 for the source gas 3 is provided at a location on the external side of the first heating device 13 and the second heating device 14, for example, at the center or lower position of the side wall.

The reaction vessel 7 extends from the inlet 2 toward the pedestal 9. The reaction vessel 7 is made of, for example, graphite or graphite whose surface is coated with a high melting point metal carbide such as TaC (tantalum carbide). The reaction vessel 7 is disposed upstream of the pedestal 9 in the flow path of the source gas 3. Due to the reaction vessel 7, the source gas 3 supplied from the inlet 2 is thermally decomposed while particles contained in the source gas 3 are eliminated before the source gas 3 is introduced to the seed crystal 5. The source gas 3 decomposed by heat in the reaction vessel 7 is supplied to the seed crystal 5. Since the surface of the seed crystal 5 becomes supersaturated with carbon and silicon atoms, a SiC single crystal 20 is precipitated on the surface of the seed crystal 5.

Specifically, the reaction vessel 7 includes a tubular member having a hollow portion, for example a hollow cylindrical member, and is disposed coaxially with the vacuum vessel 6. In the embodiment, the reaction vessel 7 is connected to the inlet 2 by narrowing its inner diameter on the side of the inlet 2 to match the inlet 2, and the source gas 3 is supplied to the surface of the seed crystal 5 after passing through the hollow portion of the reaction vessel 7. The reaction vessel 7 has a flange shape (L-shape) with an expanded outer diameter on the side adjacent to the pedestal 9, which makes it easy to guide the exhaust gas toward the outer periphery and protect the insulating material 8 from contact with the source gas 3.

The insulating material 8 suppresses the diffusion of heat toward the outer periphery of the reaction vessel 7. The insulating material 8 has a cylindrical shape arranged coaxially with the vacuum vessel 6 and the reaction vessel 7, to surround the outer peripheral surface of the reaction vessel 7. The insulating material 8 is made of, for example, graphite, or graphite whose surface is coated with a high melting point metal carbide such as TaC (tantalum carbide).

The pedestal 9 is arranged coaxially with the reaction vessel 7 and is made of, for example, graphite or graphite whose surface is coated with a high melting point metal carbide such as TaC (tantalum carbide). The seed crystal 5 is attached and held on the pedestal 9. The SiC single crystal 20 is grown on the surface of the seed crystal 5. The pedestal 9 has a shape corresponding to the shape of the seed crystal 5 to be grown, for example, in a disk shape, and is connected to the rotary lifting mechanism 12 on the surface opposite to the seed crystal 5.

The dimension of the pedestal 9, for example, the outer diameter of the pedestal 9 when the pedestal 9 is disk-shaped, is set to be equal to or larger than the inner diameter of the hollow portion of the reaction vessel 7 adjacent to the pedestal 9. The dimension of the pedestal 9 is, for example, 6 inches. Therefore, the source gas 3 supplied through the hollow portion of the reaction vessel 7 collides with the center of the pedestal 9, i.e., the center of the seed crystal 5, and is made to flow from the center toward the outer periphery of the seed crystal 5.

The guide 10 is disposed coaxially with the vacuum vessel 6 to surround the periphery of the pedestal 9, and extends downward from the upper surface of the vacuum vessel 6. The guide 10 is made of, for example, graphite or graphite whose surface is coated with a high melting point metal carbide such as TaC (tantalum carbide). The guide 10 keeps the outer surface of the SiC single crystal 20 at a predetermined temperature when the pedestal 9, the seed crystal 5, and the SiC single crystal 20 are pulled up as the SiC single crystal 20 grows. In this embodiment, the inner diameter is set to be a predetermined dimension larger than the outer diameter of the pedestal 9. Thus, the SiC single crystal 20 can be pulled up while being maintained at a predetermined distance from the guide 10.

The tip of the guide 10 closest to the reaction vessel 7 is flange-shaped (L-shaped), and is configured to protect the peripheral insulating material 11 from contact with the source gas 3. A gap of a predetermined distance is provided between the tip of the guide 10 closest to the reaction vessel 7 and the tip of the reaction vessel 7 closest to the guide 10. The reaction vessel 7 and the L-shaped tip of the guide 10 form a gas exhaust port. That is, the source gas 3 and the like are caused to flow through this gap into the space on the external side of the first heating device 13 and the second heating device 14 in the vacuum vessel 6, and discharged through the exhaust port 4.

The peripheral insulating material 11 is disposed to surround the outer periphery of the guide 10 to suppress the diffusion of heat from the guide 10 toward the outer periphery. The peripheral insulating material 11 is made of, for example, graphite or graphite whose surface is coated with a high melting point metal carbide such as TaC (tantalum carbide).

The rotary lifting mechanism 12 includes a pipe 12a, a main body 12b, and bellows 12c. One end of the pipe 12a is connected to the surface of the pedestal 9 opposite to the seed crystal 5, and the other end is connected to the main body 12b of the rotary lifting mechanism 12. The pipe 12a is made of, for example, SUS or the like. The main body 12b introduces the purge gas 16, which serves as a diluent gas, from the space between the pipe 12a and the bellows 12c while rotating and pulling up the pipe 12a. The bellows 12c constitutes an introduction space for the purge gas 16, and is disposed to surround the periphery of the pipe 12a. The bellows 12c is capable of expanding and contracting as the pipe 12a is pulled up.

With this configuration, the main body 12b introduces the purge gas 16 between the pipe 12a and the bellows 12c while rotating and pulling up the pipe 12a. This allows the rotation and pulling up of the pedestal 9, the seed crystal 5 and the SiC single crystal 20 together with the pipe 12a. The growth surface of the SiC single crystal 20 has a desired temperature distribution, while the temperature of the growth surface can be constantly adjusted to a temperature suitable for growth as the SiC single crystal 20 grows. Furthermore, since the purge gas 16 is introduced through the gap between the pedestal 9 or the seed crystal 5 and the guide 10, the source gas 3 can be restricted from entering the gap. The purge gas 16 is for diluting the source gas 3, and for example, an inert gas such as Ar or He, or an etching gas such as H₂ or HCl is used as the purge gas 16.

Each of the first heating device 13 and the second heating device 14 includes an induction heating coil, a heater, or the like. The first heating device 13 is disposed to surround the outer periphery of the reaction vessel 7 and the insulating material 8. The second heating device 14 is disposed to surround the outer periphery of the pedestal 9. In this embodiment, the second heating device 14 is disposed to surround the outer periphery of the guide 10 and the peripheral insulating material 11. The first heating device 13 and the second heating device 14 are configured so that the temperature can be controlled independently. The temperature of the areas to be heated by the first heating device 13 and the second heating device 14 can be controlled independently and precisely. That is, the reaction vessel 7 can be controlled to a temperature at which the source gas 3 can be thermally decomposed by heating the reaction vessel 7 with the first heating device 13. Furthermore, by heating the guide 10 and the growth surface of the SiC single crystal 20 with the second heating device 14, the temperature distribution on the growth surface of the SiC single crystal 20 can be adjusted to a state suitable for the growth of the SiC single crystal 20.

In this embodiment, the first heating device 13 includes a first induction heating coil 13a. The second heating device 14 includes a second induction heating coil 14a. A first coil protective tube 13b is disposed to surround the periphery of the first induction heating coil 13a, and a second coil protective tube 14b is disposed to surround the periphery of the second induction heating coil 14a, to restrict corrosion of the first induction heating coil 13a and the second induction heating coil 14a. The first coil protective tube 13b and the second coil protective tube 14b are made of a transparent material such as a quartz tube. As a corrosion-resistant structure for the first induction heating coil 13a, in addition to the structure of covering the first induction heating coil 13a with the first coil protective tube 13b, a corrosion-resistant coating may be applied to the first induction heating coil 13a. The corrosion-resistant coating may be, for example, a SiC coating or a SiO₂ coating. The same applies to the corrosion-resistant structure of the second induction heating coil 14a.

The radiation suppressing member 15 is disposed between the heated object and the first induction heating coil 13a or the second induction heating coil 14a to suppress radiation from the heated object to the first induction heating coil 13a or the second induction heating coil 14a. In this embodiment, the radiation suppressing member 15 includes a first radiation suppressing member 15a arranged between the first heating device 13 and the reaction vessel 7 or the insulating material 8, and a second radiation suppressing member 15b arranged between the second heating device 14 and the SiC single crystal 20 or the guide 10.

The first radiation suppressing member 15a suppresses radiation from the reaction vessel 7 to the first coil protective tube 13b. In this case, the reaction vessel 7 heated by the first heating device 13 correspond to a heated object. The first radiation suppressing member 15a covers the first coil protective tube 13b along the inner wall surface of the first coil protective tube 13b from the tip position to the bottom surface of the vacuum vessel 6 in the growth direction of the SiC single crystal 20. That is, the first radiation suppressing member 15a is arranged across the entire length of the first heating device 13 in the axial direction to shield the inner surface of the first heating device 13 from radiation from the heated object entirely in the axial direction. The axial direction refers to the up-down direction in FIG. 1 along the central axis of the vacuum vessel 6, the reaction vessel 7, and the like arranged coaxially to have a substantially cylindrical shape.

The second radiation suppressing member 15b suppresses radiation from the SiC single crystal 20 and the guide 10 to the second coil protective tube 14b. In this case, the SiC single crystal 20 and the guide 10 heated by the second heating device 14 correspond to a heated object. The second radiation suppressing member 15b covers the second coil protective tube 14b along the inner wall surface of the second coil protective tube 14b from the tip position to the upper surface of the vacuum vessel 6 in the growth direction of the SiC single crystal 20. That is, the second radiation suppressing member 15b is disposed across the entire width of the second heating device 14 in the axial direction to shield the inner surface of the second heating device 14 from radiation from the heated object entirely in the axial direction.

The radiation suppressing member 15 is made of material that can suppress radiation from the heated object. The radiation suppressing member 15 is preferably made of material that has discharge-resistance even at high temperatures and has lower conductivity than a conductor. It is further preferable that the radiation suppressing member 15 be made of material having a high magnetic permeability that can heat the heated object without being subjected to induction heating by the first induction heating coil 13a and the second induction heating coil 14a. The material capable of suppressing radiation from the heated object is, for example, a material capable of blocking infrared radiation radiated from the heated object. More specifically, the radiation suppressing member 15 may not be a light-transmitting material such as a transparent material. In other words, the radiation suppressing member 15 may be made of a material that has a relatively low transmittance of infrared radiation. Furthermore, when the induction heating coil uses a high-frequency coil to conduct the induction heating, arc discharge may occur, so the material is preferably resistant to discharge and difficult to pass electricity through. Furthermore, the radiation suppressing member 15 is preferable to have high magnetic permeability, since heat is generated by applying a magnetic field to the heated object to conduct the induction heating. For example, ceramics such as alumina and mullite can be used.

It is preferable that the radiation suppressing member 15 can appropriately change its shape in accordance with the thermal expansion and deformation of the reaction vessel 7 and the guide 10 as the heated object. Furthermore, the shapes of the reaction vessel 7 and the guide 10 as the heated object may become complicated due to the gas flow path structure for introducing the source gas 3 into the reaction vessel 7 and discharging the unreacted gas. Therefore, in this embodiment, the radiation suppressing member 15 is made of a fibrous member to have appropriate flexibility. Specifically, the radiation suppressing member 15 can be formed by wrapping thread made of the above-mentioned material or a woven fabric made of the thread around the reaction vessel 7 or the guide 10. Alternatively, the radiation suppressing member 15 can be formed by wrapping a nonwoven fabric made of the above-mentioned material around the reaction vessel 7 and the guide 10. The sheet-like radiation suppressing member 15 made of woven fabric or nonwoven fabric may have a single layer or multiple layers.

Next, a method for producing the SiC single crystal 20 using the SiC single crystal manufacturing apparatus 1 according to this embodiment will be described.

First, the seed crystal 5 is attached to the pedestal 9, and the first heating device 13 and the second heating device 14 are controlled to provide a desired temperature distribution. Specifically, the first heating device 13 is controlled to inductively heat the reaction vessel 7 to 2500° C., and the second heating device 14 is controlled to inductively heat the guide 10 and maintain at 2200° C. By setting the temperature at such a level, the source gas 3 to be introduced later can be thermally decomposed in the reaction vessel 7, and the source gas 3 can be recrystallized on the surface of the seed crystal 5.

While the vacuum vessel 6 is maintained at a desired pressure, the source gas 3 is introduced through the inlet 2 while a carrier gas made of an inert gas such as Ar or He or an etching gas such as H₂ or HCl, is introduced as necessary. For example, silane is introduced at a rate of 1 liter/min, propane is introduced at a rate of 0.33 liter/min, and hydrogen is introduced at a rate of 15 liter/min. As a result, the source gas 3 flows along the path indicated by the arrows in FIG. 1, and is supplied to the surface of the seed crystal 5 in a thermally decomposed state within the heated reaction vessel 7. Thus, the SiC single crystal 20 is grown on the surface of the seed crystal 5.

At this time, the purge gas 16 made of an inert gas such as Ar or He or an etching gas such as H₂ or HCl is introduced through the gap between the pipe 12a and the bellows 12c, due to the rotary lifting mechanism 12. As a result, the purge gas 16 is introduced around the pedestal 9 as indicated by the arrows in FIG. 1. Then, unreacted gas of the source gas 3 that does not reach supersaturation and does not contribute to the growth of the SiC single crystal 20 is diluted with the purge gas 16 and caused to flow through the gap between the reaction vessel 7 and the guide 10 into the space on the external side of the first heating device 13 and the second heating device 14 in the vacuum vessel 6. As a result, the constituent components of SiC contained in the unreacted gas turn into smoky particles and are deposited and removed from the bottom of the vacuum vessel 6, at the external side of the crucible such as the reaction vessel 7 and the guide 10 for growing the SiC single crystal 20 in the vacuum vessel 6.

In this manner, the SiC single crystal 20 is grown. During this process, heat radiation is generated since the reaction vessel 7, the heat insulating material 8, and the like are heated by induction heating of the first heating device 13. Similarly, since the SiC single crystal 20, the guide 10, and the like are heated by induction heating of the second heating device 14, heat radiation is generated. The heat radiation may damage the first coil protective tube 13b of the first heating device 13 and the second coil protective tube 14b of the second heating device 14.

However, in this embodiment, the first radiation suppressing member 15a is provided to cover the first coil protective tube 13b, and the second radiation suppressing member 15b is provided to cover the second coil protective tube 14b. Therefore, the radiation is blocked by the first radiation suppressing member 15a and the second radiation suppressing member 15b. Thus, the first coil protective tube 13b and the second coil protective tube 14b can be protected from the radiated heat. Accordingly, it is possible to restrict the first coil protective tube 13b and the second coil protective tube 14b from being damaged by the radiation.

As described above, in this embodiment, the radiation suppressing member 15 is arranged between the first heating device 13 and the reaction vessel 7, and is arranged between the first heating device 13 and the insulating material 8. Further, the radiation suppressing member 15 is arranged between the second heating device 14 and the SiC single crystal 20, and is arranged between the second heating device 14 and the guide 10. Therefore, even if the reaction vessel 7, the SiC single crystal 20, the guide 10, etc. are heated by the first heating device 13 or the second heating device 14 during the crystal growth of the SiC single crystal 20 such that heat radiation is generated, it is possible to block the radiation to the first coil protective tube 13b or the second coil protective tube 14b. This makes it possible to restrict the first coil protective tube 13b and the second coil protective tube 14b from being damaged by the radiation. Therefore, in the SiC single crystal manufacturing apparatus 1, damage to the first induction heating coil 13a and the second induction heating coil 14a can be suppressed.

Furthermore, the radiation suppressing member 15 according to this embodiment can effectively suppress the radiation from a heated object having a complex shape. Moreover, the shape of the radiation suppressing member 15 can be made to properly follow the deformation of the internal members of the reactor. Therefore, according to the present embodiment, it is possible to provide the SiC single crystal manufacturing apparatus 1 that is capable of performing heating for a long period of time using an induction heating coil more stably.

The present disclosure is not limited to the embodiment and the examples described above. The embodiment can be appropriately changed. Hereinafter, modifications will be described. In the following description of the modifications, differences from the embodiment will be described. In the embodiment and the modification, the same reference numerals are assigned to the same or equivalent parts. Therefore, in the following description of the modification, the description in the embodiment can be appropriately incorporated for the components having the same reference numerals as those in the embodiment, unless there is a technical contradiction or a special additional description.

The present disclosure is not limited to the specific application targets and device configurations shown in the above embodiment. For example, the present disclosure may be suitably applied to the manufacture of not only the SiC single crystal 20 but also other types of semiconductor crystals.

The configuration of the semiconductor crystal manufacturing apparatus is not limited to the specific example shown in the embodiment. For example, a configuration in which the configuration shown in FIG. 1 is inverted upside down can also be realized. Alternatively, the up-down direction in FIG. 1 may intersect with the direction of gravity. For example, a configuration in which the configuration shown in FIG. 1 is rotated clockwise by 90 degrees can also be realized. There may be no particular limitations on the configuration of the introduction path of the source gas 3 into the reaction vessel 7, the configuration of the exhaust path of the unreacted gas, the axial position of the exhaust port 4, the shape of the reaction vessel 7, and the like.

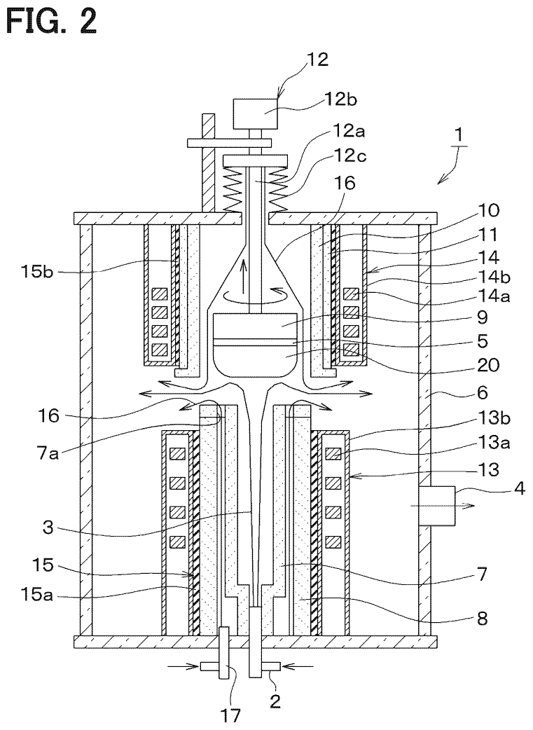

FIG. 2 is a cross-sectional view of a SiC single crystal manufacturing apparatus 1 according to a modification. As shown in FIG. 2, a through hole 7a is formed in the tip of the reaction vessel 7 adjacent to the guide 10, specifically in the flange-shaped portion. A gap is provided between the reaction vessel 7 and the insulating material 8. Furthermore, a purge gas inlet 17 is provided in the bottom surface of the vacuum vessel 6. The through holes 7a are arranged, for example, at equal intervals in the circumferential direction around the central axis of the reaction vessel 7.

In such a configuration, when the purge gas 16 is introduced from the purge gas inlet 17, the purge gas 16 is supplied to the space between the pedestal 9 and the reaction vessel 7 through the gap between the reaction vessel 7 and the insulating material 8 and through the through hole 7a. This allows the purge gas 16 to be introduced around the reaction vessel 7. Therefore, it becomes possible to dilute the unreacted gas of the source gas 3 that does not reach supersaturation and does not contribute to the growth of the SiC single crystal 20 with the purge gas 16, making it possible to further suppress clogging of the exhaust path.

As shown in FIG. 2, the gas flow path structure becomes complicated, when the purge gas 16 is introduced from the side adjacent to the reaction vessel 7. In this case, the shapes of the internal components such as the reaction vessel 7 becomes correspondingly more complicated than a simple cylindrical structure. Specifically, the internal component may have a tapered portion with increasing or decreasing diameter, steps, and the like. In this regard, in the present disclosure, flexibility is provided to the radiation suppressing member 15. Thus, it becomes possible to allow the shape of the radiation suppressing member 15 to smoothly follow the deformation of the internal component.

The constituent element(s) of each of the embodiments and the modifications is/are not necessarily essential unless it is specifically stated that the constituent element(s) is/are essential in the above embodiments, or unless the constituent element(s) is/are obviously essential in principle. In addition, in the case where the number of the constituent element(s), the value, the amount, the range, and/or the like is specified, the present disclosure is not necessarily limited to the number of the constituent element(s), the value, the amount, and/or the like specified in the embodiment unless the number of the constituent element(s), the value, the amount, and/or the like is indicated as essential or is obviously essential in view of the principle. Similarly, in the case where the shape, the direction, the positional relationship, and/or the like of the constituent element(s) is specified, the present disclosure is not necessarily limited to the shape, the direction, the positional relationship, and/or the like unless the shape, the direction, the positional relationship, and/or the like is/are indicated as essential or is/are obviously essential in principle.

The modifications are not necessarily limited to the above examples. For example, all or part of one embodiment and all or part of another embodiment can be combined together as long as there is no technical conflict. Similarly, all or part of one of the modifications and all or part of another one of the modifications may be combined with together as long as there is no technical conflict.

What is claimed is:

1. A semiconductor crystal manufacturing apparatus comprising:
a vacuum vessel into which a semiconductor source gas is supplied to a seed crystal made of a semiconductor and disposed on a pedestal to grow a crystal on a surface of the seed crystal;
a heating device including an induction heating coil to heat a heated object disposed in the vacuum vessel; and
a radiation suppressing member disposed between the heated object and the induction heating coil to suppress radiation to the induction heating coil from the heated object heated by induction heating of the induction heating coil, wherein
the radiation suppressing member is a fibrous member arranged to surround the heated object.

2. The semiconductor crystal manufacturing apparatus according to claim 1, wherein the heated object includes a hollow cylindrical member.

3. The semiconductor crystal manufacturing apparatus according to claim 1, wherein
the radiation suppressing member is made of a material that is discharge-resistant and has a lower electrical conductivity than a conductor, and
the material of the radiation suppressing member has a magnetic permeability that allows a magnetic field applied by the induction heating coil to pass through to heat the heated object.

4. The semiconductor crystal manufacturing apparatus according to claim 1, wherein the radiation suppressing member is made of ceramics.

5. The semiconductor crystal manufacturing apparatus according to claim 4, wherein the ceramics is alumina or mullite.

6. The semiconductor crystal manufacturing apparatus according to claim 1, wherein
the heating device has a coil protective member made of a transparent material to cover the induction heating coil,
the coil protective member is separate from the radiation suppressing member, and
the radiation suppressing member is located between the coil protective member and the heated object.
